(19) United States
(12) Patent Application Publication
(10) Pub. No.: US 2024/0212988 A1
(43) Pub. Date: Jun. 27, 2024

(54) DRY ETCHING METHODS FOR REDUCING FLUOROCARBON-CONTAINING GAS EMISSIONS

(71) Applicant: Winbond Electronics Corp., Taichung City (TW)

(72) Inventors: Yuan-Hao SU, Tainan City (TW); Chun-Chieh WANG, Taichung City (TW); Tzu-Ming OU YANG, Taichung City (TW)

(73) Assignee: Winbond Electronics Corp., Taichung City (TW)

(21) Appl. No.: 18/350,154

(22) Filed: Jul. 11, 2023

(30) Foreign Application Priority Data
Dec. 22, 2022 (TW) 111149406

(51) Int. Cl. H01J 37/32

(52) U.S. Cl. CPC H01J 37/32458; H01J 37/32449; H01J 37/32724; H01J 37/32816; H01J 2237/334

(57) ABSTRACT

A dry etching method for reducing fluorocarbon-containing gas emissions is provided. The method includes supplying a first gas to a reaction chamber to adjust a process parameter related to the reaction chamber. The method also includes supplying a second gas to the reaction chamber. The method further includes turning on a power source to ionize the second gas, thereby generating plasma. The plasma is used to remove part of a material layer on a substrate. The composition of the first gas is different from the composition of the second gas.

### CROSS REFERENCE TO RELATED APPLICATIONS

This application claims priority of Taiwan Patent Application No. 111149406, filed on Dec. 22, 2022, the entirety of which is incorporated by reference herein.

### BACKGROUND OF THE INVENTION

### Field of the Invention

The present invention relates to dry etching processes.

### Description of the Related Art

In dry etching processes, etchant gases are ionized (e.g. turned into plasma) to initiate chemical reactions to remove substrate material. Common etchant gases include carbon-containing compounds, halogen-containing compounds, fluorinated compounds, perfluorinated compounds (PFCs), etc. Some of the most common etchant gases are generally greenhouse gases with a relatively high carbon dioxide equivalent (CO2e). That means that these etchant gases are larger drivers of global climate change (e.g. global warming) than carbon dioxide. Therefore, reducing the amount of etchant gases that are greenhouse gases in dry etching processes is a preferred way to reduce carbon emissions, which helps tackle the greenhouse effect and achieve carbon neutrality (a state of net-zero carbon emissions).

### BRIEF SUMMARY OF THE INVENTION

According to some embodiments, a dry etching method for reducing fluorocarbon-containing gas emissions is provided. The method includes supplying a first gas to a reaction chamber to adjust a process parameter related to the reaction chamber. The method also includes supplying a second gas to the reaction chamber. The method further includes turning on a power source to ionize the second gas, thereby generating plasma. The plasma is used to remove part of a material layer on a substrate. The composition of the first gas is different from the composition of the second gas.

According to some embodiments, a dry etching method for reducing fluorocarbon-containing gas emissions is provided. The method includes supplying a first gas to a reaction chamber to adjust a process parameter related to the reaction chamber and determining whether the adjustment of the process parameter is done. After the adjustment of the process parameter is done, the method also includes stopping the supply of the first gas. The method further includes supplying a second gas to the reaction chamber and turning on a power source to ionize the second gas, thereby generating plasma. The first gas excludes fluorine.

### BRIEF DESCRIPTION OF THE DRAWINGS

FIG. 1A to FIG. 1E are views illustrating the steps before, during, and after a dry etching process, in accordance with some embodiments of the present disclosure.

FIG. 2 is a view illustrating a dry etching apparatus, in accordance with some embodiments of the present disclosure.

FIG. 3 is a top view of an electrostatic chuck (e-chuck), in accordance with some embodiments of the present disclosure.

FIG. 4 is a flow chart of a dry etching method, in accordance with some embodiments of the present disclosure.

### DETAILED DESCRIPTION OF THE INVENTION

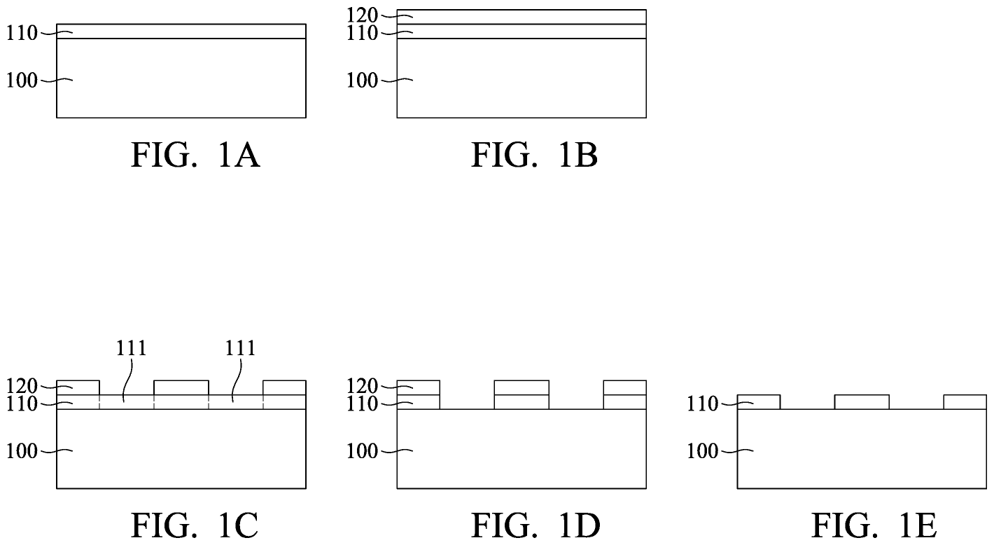

Please refer to FIG. 1A to FIG. 1E, which are views illustrating the steps before, during, and after a dry etching process, in which the step illustrated in FIG. 1D is the dry etching process. As shown in FIG. 1A, a material layer 110 is formed on a substrate 100. The substrate 100 may be a silicon wafer including silicon oxide, but the material of the substrate 100 is not limited thereto.

As shown in FIG. 1B, a photoresist layer 120 may be coated on the material layer 110. For example, the photoresist layer 120 may be formed by methods such as spin-coating, and a pre-baking process may also be performed. As shown in FIG. 1C, a desired pattern may be formed in the photoresist layer 120. For example, the photoresist layer 120 may be exposed to radiation to produce a replicated pattern of the mask, and may then be developed by a specific solution (may be referred to as the developer). The wavelengths of the radiation may be under 250 nm. For example, the radiation may be a krypton fluoride (KrF) excimer laser or an argon fluoride (ArF) excimer laser, but it is not limited thereto. As shown in FIG. 1D, a predetermined to-be-removed portion 111 (denoted in FIG. 1C) of the material layer 110 may be removed. For example, the ionized etchant gases (plasma) selectively remove the predetermined to-be-removed portion 111 of the material layer 110. As shown in FIG. 1E, the photoresist layer 120 is removed. It should be noted that the substrate 100 may include multiple material layers, and multiple dry etching processes are generally conducted on the multiple material layers of the substrate 100.

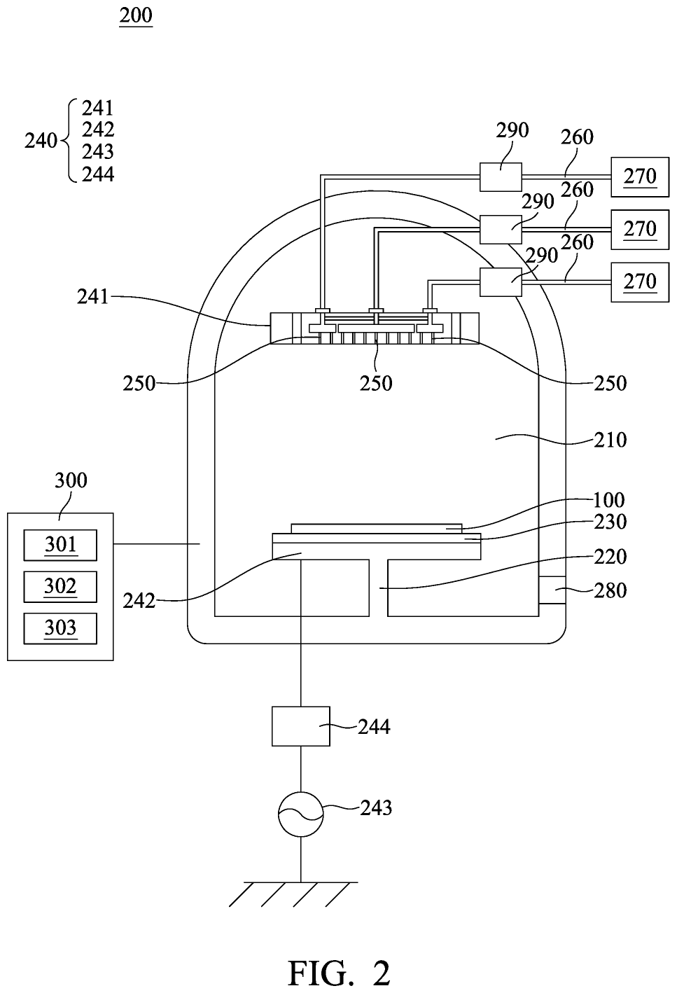

FIG. 2 is a view illustrating a dry etching apparatus 200, in accordance with some embodiments of the present disclosure. The dry etching apparatus 200 is used for performing the dry etching process. The dry etching apparatus 200 includes a reaction chamber 210, a susceptor 220, an electrostatic chuck 230, a plasma generation device 240, at least one gas inlet 250, at least one gas conduit 260, at least one gas supply source 270, and at least one gas outlet 280.

The susceptor 220 is disposed on the bottom of the reaction chamber 210. The electrostatic chuck 230 is disposed on the susceptor 220. The substrate 100 is disposed on the susceptor 220. The substrate 100 may be affixed via the electrostatic chuck 230. For example, the substrate 100 may be affixed to the electrostatic chuck 230 due to the electrostatic force (also may be referred to as the Coulombic force) generated by the electrostatic chuck 230.

The plasma generation device 240 may include a pair of parallel electrodes (including an upper electrode 241 and a lower electrode 242), a power source 243, and a matching unit 244. The upper electrode 241 and the lower electrode 242 are disposed in the reaction chamber 210. The upper electrode 241 and the lower electrode 242 may be a pair of anode and cathode, and the upper electrode 241 and the lower electrode 242 may be disposed on opposite sides of the interior of the reaction chamber 210. The power source 243 may be a high-frequency power source, and it may be connected to the lower electrode 242 via the matching unit 244. The power source 243 may make the gases in the reaction chamber 210 ionized to generate plasma to remove the predetermined to-be-removed portion 111 of the material layer 110.

The gas inlet 250 is connected to the gas conduit 260 to direct the gas from the gas supply source 270 into the reaction chamber 210. In the embodiment illustrated in FIG. 2, there are three gas supply sources 270, but the number of the gas supply sources 270 is not limited thereto. There may be more or less gas supply sources 270 according to actual need. The gas supplied by the gas supply sources 270 may include an inert gas, a carbon-containing gas, a fluorine-containing gas, a fluorocarbon-containing gas, and the like, such as, He, Ne, Ar, Ke, Xe, Rn, Cl₂, HBr, CF₄, CHF₃, CH₂F₂, SF₆, N₂, O₂, carbonyl sulfide or COS, etc., but it is not limited thereto.

Different gases from different gas supply sources 270 may be introduced into the reaction chamber 210 via the respective gas conduit 260 and the respective gas inlet 250, such that the gases in the reaction chamber 210 is the mixture of different gases from different gas supply sources 270. In some embodiments, for each gas conduit 260, there may be a mass flow controller (MFC) 290 for controlling the gas flow rate of the gas from the gas supply source 270. The gas outlet 280 is formed on one side of the reaction chamber 210, and it may be connected to an exhaust device (e.g. a pump) for exhausting the gases in the reaction chamber 210.

In addition, a control device 300 may be used for controlling the dry etching apparatus 200. The control device 300 may include a central process unit (CPU) 301, a memory 302, a user interface 303, etc. to store the recipe of the dry etching process and control the dry etching process.

In the dry etching process, before the power source 210 is turned on to ionize the gases in the reaction chamber 210, one or more process parameters related to the reaction chamber 210 may first be adjusted to a predetermined value to ensure the dry etching process has good yield and stability. For ease of explanation, in the following description, the period for adjusting the process parameters may be referred to as “the adjustment period”, and the period after the adjustment is done and until the predetermined to-be-removed portion 111 of the material layer 110 is removed is referred to as “the reaction period.” Typically, the adjustment period is shorter than the reaction period. Also, any gases supplied during the adjustment period are referred to as “the first gas”, and any gases supplied during the reaction period (such as ionized gas) are referred to as “the second gas.”

In a conventional dry etching process, the gas used is not sorted into different gases (for example, the first gas and the second gas). That is, in a conventional dry etching process, the etchant gases used in the entire dry etching process are the same, so the usage and emission of greenhouse gases are large (as described above, the most common etchant gases are greenhouse gases).

In contrast to conventional dry etching processes, in the dry etching process of the present disclosure, the composition of the first gas supplied during the adjustment period is different from the composition of the second gas supplied during the reaction period, so the usage and emission of greenhouse gases may be reduced. In particular, the percentage of greenhouse gases in the first gas is less than the percentage of greenhouse gases in the second gas.

In some embodiments, the first gas excludes greenhouse gases and consists of non-greenhouse gases, so usage and emissions of greenhouse gases may be further reduced. That is, the first gas does not include other gases except for non-greenhouse gases. For example, the first gas may not include fluorocarbon compounds. For example, the first gas may not include halogens. For example, the first gas may not include fluorine.

In some embodiments, the first gas consists of inert gases. That is, the first gas does not include other gases except for the inert gases. In some embodiments, the first gas consists of only one gas. For example, the first gas may consist of Ar. That is, the first gas does not include other gases except for Ar.

It should be noted that, “gases with different compositions” may be understood as gases that include different types of gases or gases having the same types of gases but with different percentages. For example, the first gas and the second gas may include the same gas, but the percentage of such gas in the first gas is different from the percentage of such gas in the second gas. For example, if the first gas contains 80% Ar and the second gas contains 20% Ar, the first gas and the second gas may be regarded as having different compositions.

Typically, during the manufacture processes, for each substrate 100, dry etching processes are performed multiple times, so carbon emissions may be reduced effectively and significantly. For example, compared to the conventional dry etching process, the dry etching process described in the present disclosure may result in 0.1%-40% reduction in carbon emissions for manufacture of each substrate 100. It should be noted that in the same dry etching process, the gas flow rate of the first gas is typically the same as the gas flow rate of the second gas to ensure the process parameters maintain in a narrow range to ensure performance consistency. However, in different dry etching processes, the gas flow rate of the first gas and the gas flow rate of the second gas may be adjusted to another value. In addition, in different dry etching processes, the composition of the second gas may be different, but the composition of the first gas may be the same to simplify process design.

As described above, in the present disclosure, in the dry etching process, the composition of the first gas supplied during the adjustment period is different from the composition of the second gas supplied during the reaction period, so usage and emissions of greenhouse gases may be reduced. Therefore, carbon emissions are reduced, helping to tackle the greenhouse effect and achieve carbon neutrality. In addition, the first gas may not include greenhouse gases and may consist of only one gas to further reduce carbon emissions. Furthermore, the first gas is typically cheaper than the second gas, so manufacturing cost may also be reduced.

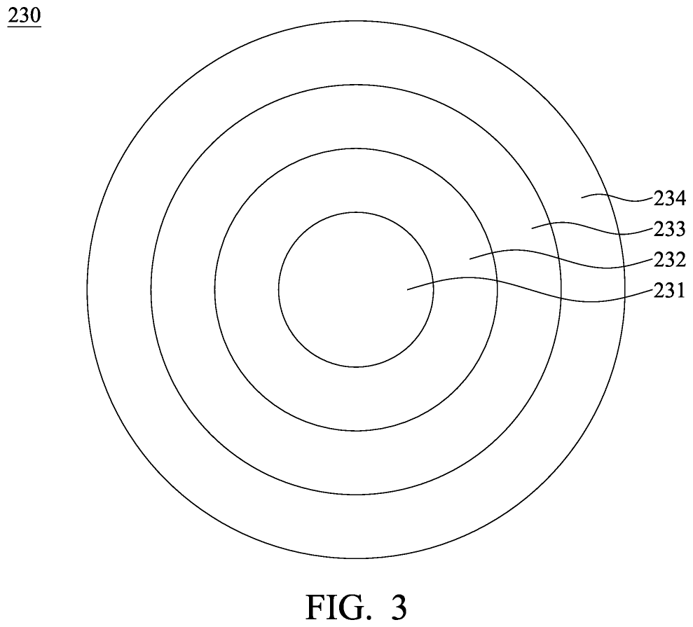

Next, please refer to FIG. 2 and FIG. 3 to understand the adjustment of the process parameters. FIG. 3 is a top view of the electrostatic chuck 230, in accordance with some embodiments of the present disclosure. In some embodiments, the process parameters may include the pressure of the reaction chamber 210, the temperature of the electrostatic chuck 230, the voltage of the power source, the gas flow rate of the gas (e.g. the first gas and the second gas), but the process parameters are not limited thereto.

In some embodiments, the predetermined pressure of the reaction chamber 210 may be between about 0.001 Pa (Pascal) to about 0.050 Pa. For example, the predetermined pressure of the reaction chamber 210 may be set as 0.004 Pa, 0.005 Pa, 0.015 Pa, 0.020 Pa, etc. In some embodiments, the predetermined temperature of the electrostatic chuck 230 may be between about 20° C. to about 50° C. For example, the predetermined temperature of the electrostatic chuck 230 may be set as 20° C., 26° C., 28° C., 30° C., 35° C., 40° C., 42° C., etc.

In some embodiments, the adjustment of the process parameters may include measuring the actual pressure of the reaction chamber 210 and determining whether the difference between the actual pressure of the reaction chamber 210 and the predetermined pressure of the reaction chamber 210 is within 10%. In some embodiments, the adjustment of the process parameters may include measuring the actual temperature of the electrostatic chuck 230 and determining whether the difference between the actual temperature of the electrostatic chuck 230 and the predetermined temperature of the electrostatic chuck 230 is within 10%.

It should be noted that, in some embodiments, the electrostatic chuck 230 may include a plurality of regions, and the temperature of each region may be controlled separately to enhance etching uniformity of dry etching process. As shown in FIG. 3, in this embodiment, the electrostatic chuck 230 includes four regions 231, 232, 233, 234, and the electrostatic chuck 230 is divided into four equal parts in the radial direction (i.e., as regions 231, 232, 233, 234). The regions 231, 232, 233, 234 are arranged as concentric circles. In some embodiments, every region 231, 232, 233, 234 has the same predetermined temperature. In some embodiments, the innermost region 231 and the outermost region 234 have the same predetermined temperature, and the two intermediate regions 232, 233 both have another predetermined temperature. In some embodiments, the predetermined temperature of the regions 231, 232, 233, 234 gradually increases or decreases in the radial direction. However, the predetermined temperature may be set arbitrarily to suit actual needs. In addition, the number of regions of the electrostatic chuck 230 may be changed. Table 1, which includes different embodiments, is provided for reference below:

| | The | The | The | The |
|---|---|---|---|---|
| | predetermined | predetermined | predetermined | predetermined |
| | temperature of | temperature of | temperature of | temperature of |
| | the region 231 | the region 232 | the region 233 | the region 234 |
| Embodiment 1 | 40° C. | 40° C. | 40° C. | 40° C. |
| Embodiment 2 | 40° C. | 35° C. | 35° C. | 40° C. |
| Embodiment 3 | 42° C. | 36° C. | 26° C. | 26° C. |
| Embodiment 4 | 26° C. | 30° C. | 34° C. | 38° C. |

In some embodiments, when the difference between the actual pressure of the reaction chamber 210 and the predetermined pressure of the reaction chamber 210 is within 10% and/or the difference between the actual temperature of the regions 231, 232, 233, 234 of the electrostatic chuck 230 and the predetermined temperature of the regions 231, 232, 233, 234 of the electrostatic chuck 230 is within 10%, it is determined that the adjustment is done. When the adjustment is done, stop supplying the first gas and begin to supply the second gas. Also, the power source is turned on to ionize the second gas, thereby generating plasma. Having the standard whether the adjustment is done helps process automation and simplification of manufacturing.

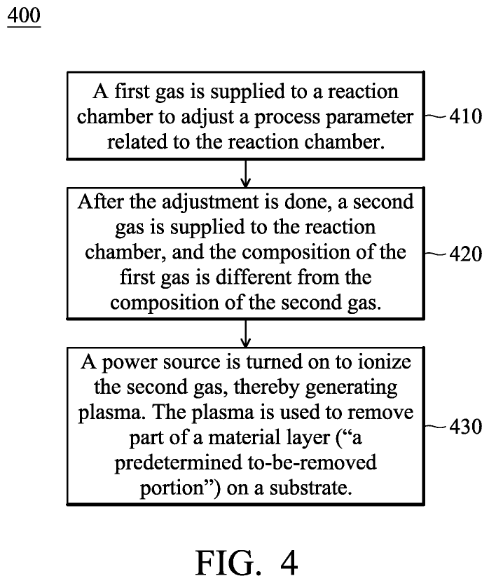

FIG. 4 is a flow chart of a dry etching method 400, in accordance with some embodiments of the present disclosure. The dry etching method 400 includes steps 410, 420, 430. In the step 410, a first gas is supplied to a reaction chamber to adjust a process parameter related to the reaction chamber. The process parameter may include the pressure of the reaction chamber, the temperature of the electrostatic chuck, the voltage of the power source, the gas flow rate of the gas, etc.

In the step 420, after the adjustment is done, a second gas is supplied to the reaction chamber, and the composition of the first gas is different from the composition of the second gas. The adjustment of the process parameter may include measuring the actual value of the process parameter and calculating whether the difference between the actual value of the process parameter and the predetermined value of the process parameter is within 10%. Also, the percentage of greenhouse gases in the first gas is less than the percentage of greenhouse gases in the second gas. In the step 430, a power source is turned on to ionize the second gas, thereby generating plasma. The plasma may be used to remove part of a material layer (may be referred to as “a predetermined to-be-removed portion”) on a substrate.

Based on the present disclosure, in a dry etching process, during the adjustment period, etchant gases contain greenhouse gases are replaced with the first gas that has a different composition. Therefore, carbon emissions are reduced, helping to tackle the greenhouse effect and achieve carbon neutrality. For example, compared to the conventional dry etching process, the dry etching process described in the present disclosure may result in 0.1%-40% reduction in carbon emissions for manufacture of each substrate. In addition, the first gas may consist of non-greenhouse gases that are cheaper, so usage and emissions of greenhouse gases may be further reduced and manufacturing costs may also be reduced. Furthermore, the present disclosure also provides details regarding the adjustment of process parameters, which facilitates determining whether the adjustment is done. Having the standard whether the adjustment is done helps process automation and simplification of manufacturing.

The foregoing outlines features of several embodiments, so that those skilled in the art may better understand the aspects of this disclosure. Those skilled in the art should appreciate that they may readily use this disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of this disclosure.

What is claimed is:

1. A dry etching method for reducing fluorocarbon-containing gas emissions, comprising:
supplying a first gas to a reaction chamber to adjust a process parameter related to the reaction chamber;
supplying a second gas to the reaction chamber;
turning on a power source to ionize the second gas, thereby generating plasma; and
using the plasma to remove part of a material layer on a substrate, wherein a composition of the first gas is different from a composition of the second gas.

2. The dry etching method as claimed in claim 1, wherein a percentage of greenhouse gases in the first gas is less than a percentage of greenhouse gases in the second gas.

3. The dry etching method as claimed in claim 1, wherein the first gas excludes fluorine.

4. The dry etching method as claimed in claim 1, wherein the first gas excludes fluorocarbon compounds.

5. The dry etching method as claimed in claim 1, wherein the first gas consists of an inert gas.

6. The dry etching method as claimed in claim 1, wherein the first gas consists of Ar.

7. The dry etching method as claimed in claim 1, wherein a gas flow rate of the first gas and a gas flow rate of the second gas are equal.

8. The dry etching method as claimed in claim 1, wherein the adjustment of the process parameter comprises measuring an actual pressure of the reaction chamber and determining whether a difference between the actual pressure of the reaction chamber and a predetermined pressure of the reaction chamber is within 10%.

9. The dry etching method as claimed in claim 1, wherein the reaction chamber comprises an electrostatic chuck, the substrate is disposed on the electrostatic chuck, and the adjustment of the process parameter comprises measuring an actual temperature of the electrostatic chuck and determining whether a difference between the actual temperature of the electrostatic chuck and a predetermined temperature of the electrostatic chuck is within 10%.

10. The dry etching method as claimed in claim 9, wherein the electrostatic chuck comprises a plurality of regions, and a temperature of each of the regions is controlled separately.

11. A dry etching method for reducing fluorocarbon-containing gas emissions, comprising:
supplying a first gas to a reaction chamber to adjust a process parameter related to the reaction chamber;
determining whether the adjustment of the process parameter is done, wherein after the adjustment of the process parameter is done, stopping the supply of the first gas;
supplying a second gas to the reaction chamber; and
turning on a power source to ionize the second gas, thereby generating plasma, wherein the first gas excludes fluorine.

12. The dry etching method as claimed in claim 11, wherein a percentage of greenhouse gases in the first gas is less than a percentage of greenhouse gases in the second gas.

13. The dry etching method as claimed in claim 11, wherein the first gas excludes fluorocarbon compounds.

14. The dry etching method as claimed in claim 11, wherein the first gas consists of an inert gas.

15. The dry etching method as claimed in claim 11, wherein the first gas consists of Ar.

16. The dry etching method as claimed in claim 11, wherein a period for supplying the first gas is shorter than a period for supplying the second gas.

17. The dry etching method as claimed in claim 11, wherein a gas flow rate of the first gas and a gas flow rate of the second gas are equal.

18. The dry etching method as claimed in claim 11, wherein the adjustment of the process parameter comprises measuring an actual pressure of the reaction chamber and determining whether a difference between the actual pressure of the reaction chamber and a predetermined pressure of the reaction chamber is within 10%.

19. The dry etching method as claimed in claim 11, wherein the reaction chamber comprises an electrostatic chuck, and the adjustment of the process parameter comprises measuring an actual temperature of the electrostatic chuck and determining whether a difference between the actual temperature of the electrostatic chuck and a predetermined temperature of the electrostatic chuck is within 10%.

20. The dry etching method as claimed in claim 19, wherein the electrostatic chuck comprises a plurality of regions, and a temperature of each of the regions is controlled separately.
